(19) United States
(12) Patent Application Publication
(10) Pub. No.: US 2021/0202825 A1
(43) Pub. Date: Jul. 1, 2021

(54) ENERGY HARVESTER COMPRISING A PIEZOELECTRIC MATERIAL-BASED CONVERTER

(71) Applicant: Enerbee, Grenoble (FR)

(72) Inventors: Luc Pouyadou, Brignoud (FR); Thibault Ricart, Seyssinet Pariset (FR); Jérôme Delamare, Quaix en Chartreuse (FR); Romain Soulie, Grenoble (FR)

(21) Appl. No.: 16/757,323

(22) PCT Filed: Oct. 15, 2018
(86) PCT No.: PCT/FR2018/052555

§ 371 Date: Apr. 17, 2020

(30) Foreign Application Priority Data
Oct. 18, 2017 (FR) 1759763

(51) Int. Cl. H01L 41/113; H02N 2/18

(52) U.S. Cl. CPC H01L 41/113; H02N 2/186; H02N 2/181

(57) ABSTRACT

An energy harvester comprises: converter capable of converting a variation of energy to be harvested into a potential difference between two electric terminals by accumulating charges; the converter including a stack of layers with at least one first layer made of a piezoelectric material; a collection circuit connected to the terminals and comprising a switch, the collection circuit being configured to harvest the charges when the switch is in a closed state; the converter being able to emit acoustic vibrations in an audible frequency band when the collection circuit harvests the charges; the energy harvester further comprises a control circuit configured to control a plurality of closing-opening sequences (S_{FO}) of the switch, when the potential difference reaches a defined threshold, so as to harvest the charges through a plurality of partial discharges of the converter and to limit the stress deviation experienced by the first layer during each discharge.

### CROSS-REFERENCE TO RELATED APPLICATIONS

This application is a national phase entry under 35 U.S.C. § 371 of International Patent Application PCT/FR2018/052555, filed Oct. 15, 2018, designating the United States of America and published as International Patent Publication WO 2019/077248 A1 on Apr. 25 2019, which claims the benefit under Article 8 of the Patent Cooperation Treaty to French Patent Application Serial No. 1759763, filed Oct. 18, 2017.

### TECHNICAL FIELD

The present disclosure relates to the field of devices for energy harvesting. It relates, in particular, to an energy harvester comprising a converter that is capable of converting a change in energy to be harvested into a potential difference. The converter comprises a piezoelectric material layer.

### BACKGROUND

Electricity generators comprising a magnetic field source and an energy harvester are known from the prior art (WO2014/063951 and WO2014/063958). The energy harvester comprises a magneto-electric converter that is capable of converting a change in the magnetic field into a potential difference between two electrical terminals by accumulating electric charge on one or other of the electrical terminals. The converter is made up of an electromechanical transducer, comprising a piezoelectric layer that is capable of transforming a mechanical deformation into a potential difference between the electrodes thereof, which are connected to two electrical terminals. The converter is also made up of a magnetostrictive layer that is fixed to the electromechanical transducer according to a reference plane and without any degree of freedom and that is capable of converting a change in the magnetic field into a mechanical deformation exerted on the electromechanical transducer. The energy harvester also comprises a charge collection circuit that is connected to the electrical terminals of the converter by means of a switch, and the switch is controlled so as to toggle to a closed position, for allowing for harvesting of all the charges, accumulated on one of the electrical terminals of the converter, once the potential difference between the electrical terminals is greater than a predetermined threshold.

During operation, generators of this kind emit a knocking sound. This soundwave may have a braking, or even redihibitory, effect for some applications.

### BRIEF SUMMARY

An object of the present disclosure is that of proposing a solution for limiting or eliminating the soundwave generated by the generators of the prior art.

The present disclosure relates to an energy harvester comprising:
a converter that is capable of converting a change in the energy to be harvested into a potential difference between two electrical terminals by means of accumulation of charges on one or other of the terminals; the converter includes a layer stack comprising at least one first layer made of a piezoelectric material;
a collection circuit that is connected to the two electrical terminals and comprises a switch, the collection circuit being designed to harvest the charges when the switch is in the closed state; the converter is capable of emitting acoustic vibrations in an audible frequency band when the collection circuit harvests the charges;

The energy harvester is distinctive in that it comprises a control circuit that is designed for controlling a plurality of closing/opening sequences of the switch when the potential difference reaches a defined threshold, so as to harvest the charges by means of a plurality of partial discharges of the converter, and to limit the stress deviation to which the first layer is subjected during each discharge.

According to advantageous features of the converter according to the present disclosure, taken individually or in combination:
for each sequence, the closed state of the switch is controlled by a pulse generated by the control circuit;
the at least one width of the plurality of pulses, and the period of the pulses, are selected so as to control the stress dynamics to which the first layer is subjected during the partial discharges;
a pulse has a width of 100 to 1000 nanoseconds, and two pulses of two consecutive sequences are spaced apart by 10 to 100 microseconds;
the control circuit comprises a first stage for detecting a defined threshold of the potential difference, a second stage of generating the pulses, and a third stage of controlling the switch;
the first stage comprises a differential comparator that is connected to the electrical terminals of the converter and is capable of generating a first trigger signal in the region of a first outlet;
the second stage comprises a logic device that is connected to the first outlet and is capable of generating a second signal that forms a pulse train, in the region of a second outlet;
the second signal has a fixed pulse width, pulse period and number of pulses;
the third stage comprises an adaptation device that is connected to the second outlet and is intended for transforming the second signal into a control signal that forms a pulse train and is capable of controlling the plurality of closing/opening sequences of the switch;
the adaptation device comprises a transistor and a pulse transformer;
the second stage or the assembly formed by the first and the second stage comprises a microcontroller that is designed for generating a second signal that forms a pulse train, in the region of a second outlet;
the second signal has a variable pulse width, pulse period and number of pulses;
the converter is a magneto-electric converter, which is capable of converting a change in magnetic energy into a potential difference between the two electrical terminals thereof, and the layer stack of which comprises a second layer made of a magnetostrictive material.

The present disclosure also relates to an electricity generator comprising a magnetic field source and an energy harvester as above.

### BRIEF DESCRIPTION OF THE DRAWINGS

Other features and advantages of the present disclosure will become clear from the following detailed description of the present disclosure, with reference to the accompanying drawings, in which:

FIG. 1 shows an electricity generator comprising an energy harvester according to the present disclosure;

FIG. 2 is a wiring diagram of an energy harvester according to the present disclosure;

FIGS. 3a and 3b show examples of the periodic change of the potential difference at the electrical terminals of a converter;

FIGS. 4a and 4b show examples of the periodic change of the potential difference at the electrical terminals of a converter of an energy harvester according to the present disclosure;

FIGS. 5a and 5b are each wiring diagrams of the first stage of a control circuit of an energy harvester according to the present disclosure;

FIG. 6 is a wiring diagram of the second stage of the control circuit of an energy harvester according to the present disclosure;

FIG. 7 is a wiring diagram of the third stage of the control circuit of an energy harvester according to the present disclosure.

### DETAILED DESCRIPTION

The figures show embodiments and should not, in any event, be considered limiting. The same reference signs in the figures may be used for identical objects.

The present disclosure relates to an energy harvester 90 that is intended to form a part of an electricity generator 100.

The energy harvester 90 comprises a converter 10 that is capable of converting a change in the energy to be harvested into a potential difference between two electrical terminals 11, 12 by means of accumulation of charges on one or other of the terminals 11, 12.

The converter 10 comprises a layer stack 9 comprising at least one first layer 1 made of a piezoelectric material, the first layer 1 comprising two metal electrodes that are electrically connected to two electrical terminals 11, 12. Mechanical deformation (due to a change in ambient energy to be harvested) of the first layer 1 leads to the generation of charges on one or other of the electrodes, which charges will subsequently be harvested within the electricity generator 100.

The layer stack 9 of the converter 10 may be made up of additional layers made of different materials, depending on the type and mode of operation of the converter 10. In particular, the converter 10 may be of the magneto-electric type, which is capable of converting a change in magnetic energy into a potential difference between the two electrical terminals 11, 12 thereof. In this case, as described in the prior art documents mentioned in the introduction, the layer stack may comprise a second layer 2 that is made of a magnetostrictive material and is fixed to the first layer 1 of piezoelectric material, according to the plane of reference of the first layer and without degree of freedom.

A change of magnetic energy leads to deformation of the second layer 2 of magnetorestrictive material, which deformation is applied to the first layer 1 of piezoelectric material that is integral with the second layer 2 in the stack 9.

The change of magnetic energy typically results from the movement of a magnetic field source 50, the source being part of the electricity generator 100. The magnetic field source 50 must be able to perform a relative movement with respect to the layer stack 9 of the converter 10, in order to bring about a change in the magnetic energy.

In the embodiment of the generator shown in FIG. 1, the converter 10 is formed by a layer stack 9 that is integral with a connection layer 13 that ensures the electrical connection between the electrodes of the first layer 1 and the electrical terminals 11, 12. The converter 10 is circular in shape, in the plane perpendicular to the axis Z, and is held in a stationary manner by a mechanical support 20. The magnetic field source 50 is annular in shape and is capable of performing a rotational movement about the axis Z.

By way of example, this rotational movement of the magnetic field source 50 may be associated with the manipulation of a dimmer switch by a user (for example, in order to control a light), or the rotation of a turbine in a ventilation duct.

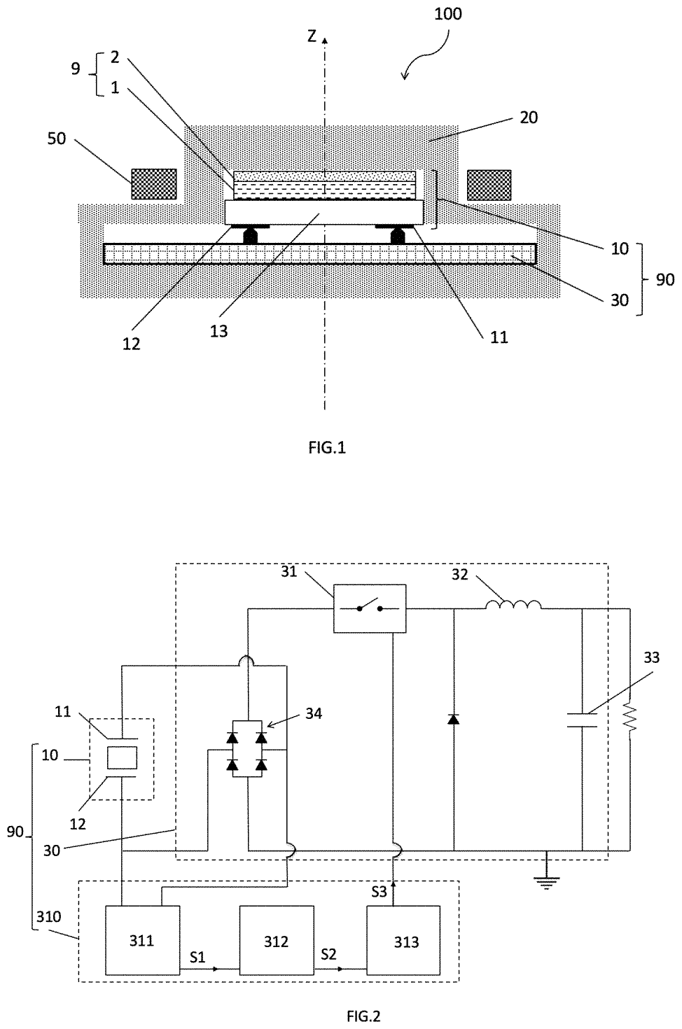

Thus, the change in energy to be harvested is converted into charges by the converter 10, which charges are subsequently harvested within the energy harvester 90 by means of a charge collection circuit 30 that is electrically connected to the two electrical terminals 11, 12 of the converter 10. The collection circuit 30 typically comprises an inductive element 32 (for example, a coil) and a switch 31 (FIG. 2). In the closed position, the switch allows for charges to flow toward the inductive element 32, which is connected to an electrical load that is capable of storing electrical energy, such as a capacitor 33. This electrical energy can be used to supply an electronic component. Returning to the embodiments cited above, the component could control switching a light on and off, or even the measurement, display or recording of parameters of a ventilation duct.

The switch 31 is closed when the potential difference between the electrical terminals 11, 12 reaches a specified threshold. Advantageously, from an energy viewpoint the specified threshold is substantially the maximum level of potential difference that can be obtained by the converter 10, with the aim of harvesting maximum charges and thus maximum energy.

The applicant has found that, during operation, an electricity generator 100 provided with an energy harvester 90 as described above generates a knocking sound. Although this is not disturbing in applications of the dimmer switch type, this sound is much more disruptive when the electricity generator 100 is used in ventilation ducts of inhabited places. Indeed, this knocking noise, which can be heard by the users of the places, is a real sound nuisance.

The applicant has carried out various investigations in order to identify the origin of this knocking sound. Various theories have been put forward, including, in particular, the effect of the generation of current pulses in the inductive element 32 upon opening of the switch 31 of the collection circuit 30 for harvesting charges, bringing about a deformation of the turns of the coil. Another theory was the effect of the very fast discharge of the first layer 1 of piezoelectric material, bringing about a sudden change in the state of stress in the first layer.

Ultimately it was this second theory that was verified. The applicant established that the soundwave was due primarily to acoustic vibrations, generated by the sudden change in the state of stress of the first layer 1 of piezoelectric material during harvesting of the charges. The phenomenon of electrical discharge of the converter (flow of charges from one of the electrical terminals of the converter 10 to the inductive element 32 of the collection circuit 30) results in the potential between the terminals 11, 12 thereof going from several tens of volts, or even several hundreds of volts, to zero, in a fraction of a second. The change in the state of stress of the first layer 1 of the piezoelectric material is therefore abrupt, and generates acoustic vibrations that are transmitted to the converter 10 and to all the elements of the electricity generator 100.

The applicant particularly analyzed the flow time of the charges upon opening of the switch 31, in order to evaluate the possibilities of dividing the charge harvesting into a plurality of sequences (successive partial discharges), with the aim of limiting the stress deviation to which the first layer 1 is subjected, between the state thereof prior to discharge and the state thereof after discharge.

It has been noted that the time for a complete discharge of the converter is in the region of 3 microseconds.

Thus, the energy harvester 90 according to the present disclosure comprises a control circuit 310 that is designed for controlling a plurality of closing/opening sequences of the switch 31 when the potential difference reaches a defined threshold, so as to harvest the charges by means of a plurality of partial discharges of the converter.

The sequential flow of just parts of the charges accumulated on one of the electrical terminals 11, 12 makes it possible to manage the change in the state of stress of the first layer 1 of piezoelectric material. For each discharge sequence, the stress deviation to which the first layer 1 is subjected is limited, and thus does not generate any, or generates only a small amount of, acoustic vibrations.

Advantageously, for each sequence, the closed state of the switch 31 is controlled by a pulse generated by the control circuit 310. A pulse typically has a width of 10 to 1000 nanoseconds, two pulses of two consecutive sequences are typically spaced apart by 10 to 100 microseconds, and the pulse train has a total duration of less than 3 ms.

The selection of the features of the pulses (width, period, number of pulses) can vary depending on the value of the potential difference at the terminals 11, 12 of the converter 10, and depending on the piezoelectric material of the first layer 1.

The width of the pulses (closure time of the switch 31) has to be adjusted in order to harvest a sufficiently small amount of charge that the stress deviation to which the first layer 1 is subjected between the state before discharge and the state after discharge does not generate an acoustic vibration or at least that the vibration is small and inaudible (for example, less than 25 dBA).

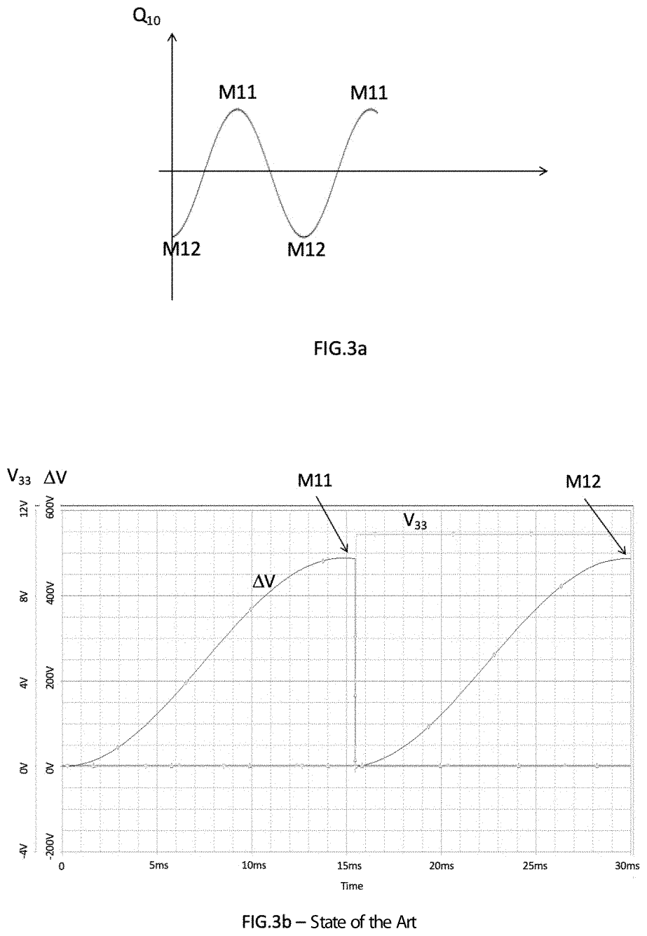

Furthermore, for reasons of effectiveness it is important to completely discharge the converter 10. It is noted that the change of energy to be harvested in electricity generator 100 is often periodic, and the converter 10 is therefore designed to generate a maximum amount of charge, on one and then on the other of the electrical terminals, alternately, in accordance with a periodicity that is associated with the period of the change in energy to be harvested. For example, the maximum amount of charges Q₁₀ on the electrical terminals 11, 12 of the converter 10, if the charges are not collected, can vary, as shown in FIG. 3, passing alternately through a peak (maximum) of positive charges M11 on the electrical terminal 11 and a peak of negative charges M12 on the electrical terminal 12.

The charges are advantageously collected at each charge peak M11, M12 corresponding to a potential difference Δv maximum between the two electrical terminals 11, 12. This makes it possible to make maximum use of the cycles of deformations of the first layer 1 of the converter 10 made of piezoelectric material. Alternatively, it is possible to choose to trigger the collection of charges before reaching the charge maximum M11 or M12, i.e., for a specified potential difference Δv threshold between the two electrical terminals 11, 12.

Since the potential difference Δv between the two electrical terminals 11, 12 is, alternately, positive and negative, a diode bridge 34 (FIG. 2) makes it possible to rectify this at the input of the collection circuit 30.

As shown in FIG. 3b, following closure of the switch 31, the discharge of the converter 10 (in a sequence, according to the prior art) is very quick (a few microseconds), and corresponds to the time for transferring the energy thereof to the inductive element 32. The charge of the capacitor 33 is slightly longer, and corresponds to the transfer of energy from the inductive element 32 to the capacitor 33 (around 100 microseconds). It will be noted that, given the scale of the graph in FIG. 3b, it is not possible to identify the duration of the increase in voltage V₃₃ at the terminals of the capacitor 33.

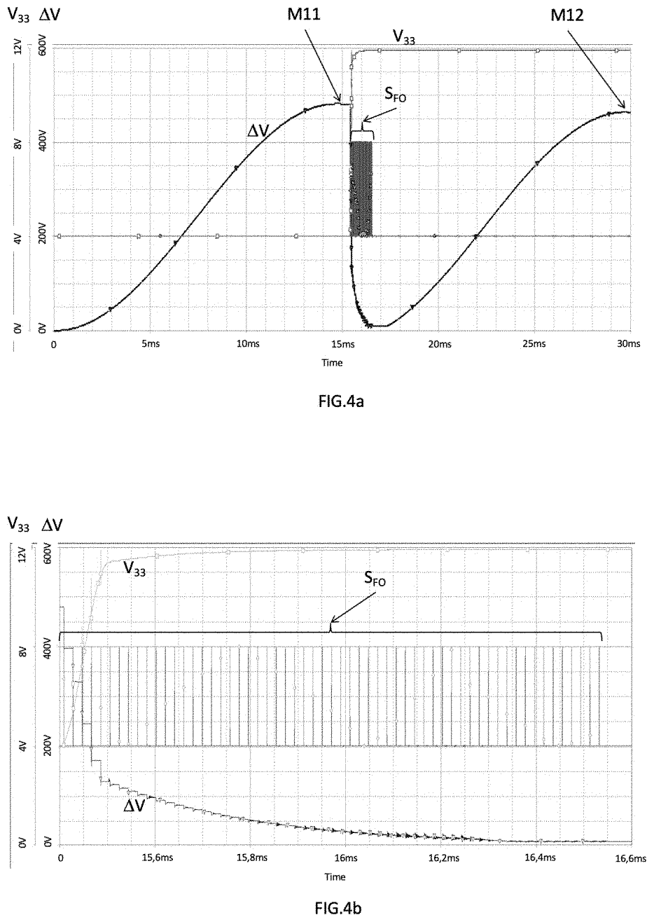

For reasons of effectiveness, the complete discharge of the converter 10 in the energy harvester 90 according to the present disclosure thus involves linking a plurality of pulses (corresponding to a plurality of closing/opening sequences S_{FO} of the switch 31) in order to achieve a potential difference of zero between the terminals 11, 12 of the converter 10, as shown in FIGS. 4a and 4b. As mentioned above, the number of pulses can thus vary depending on the value of the potential difference Av at the terminals 11, 12 of the converter 10, and depending on the piezoelectric material of the first layer 1.

Finally, the discharge of the converter 10 must be carried out within a limited time, before the charges accumulated in the converter 10 can be cancelled out by an inverse deformation of the first layer 1. The period of the pulse train must therefore make it possible to discharge all the accumulated charges, before they are balanced out within the first layer 1. In other words, the time allotted for the pulse train (i.e., the plurality of closing-opening sequences of the switch 31) has to remain much smaller than the period associated with the change in the energy of the electricity generator 100 to be harvested.

However, in a correlative manner, it should be ensured that sufficient time remains between each discharge sequence in order for the successive discharges not to have the same effect, in mechanical terms, as discharge in one single pulse (generation of acoustic vibrations), i.e., that the first layer 1 has sufficient relaxation time between each state of stress. Thus, the width (or the widths) of the pulses, and the period of the pulses, must also be selected so as to control the stress dynamics to which the first layer 1 is subjected during the successive partial discharges.

Advantageously, the control circuit 310 comprises:
a first stage 311 of detecting the specified threshold of the potential difference; the first stage 311 is designed for detecting the threshold between the electrical terminals 11, 12 of the converter 10 and for generating a trigger signal (referred to as the first signal) at a first outlet S1;
a second stage 312 of generating the pulses; the second stage 312, connected to the first outlet S1, is designed to generate a signal that forms a pulse train (referred to as the second signal), at a second outlet S2, when it receives the first trigger signal;
and a third stage 313 of controlling the switch 31; the third stage 313, which is connected to the second outlet S2 is intended for transforming the second signal into a control signal that forms a pulse train; the control signal at the third outlet S3 is capable of controlling the plurality of closing/opening sequences of the switch 31.

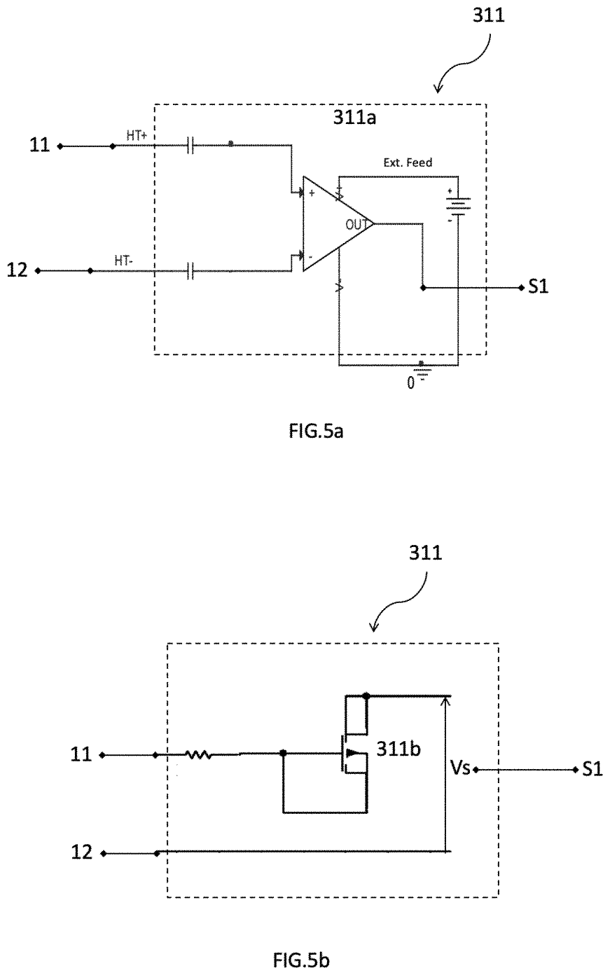

According to a first embodiment, the first stage 311 of detecting the specified threshold comprises a differential comparator 311a that is connected to the electrical terminals 11, 12 of the converter 10 (FIG. 5a).

Advantageously, from an energy perspective, the switch 31 is triggered when the potential difference Δv at the terminals 11, 12 of the converter 10 is at a maximum (peak value). For this purpose, it is possible to use a differential comparator 311a formed of an amplifier connected to an external source for measuring the high-voltage signal Δv. Detection of the peak is achieved by the signal derivative at the terminals of the converter 10, and its passing through 0 is detected. This derivative is achieved, analogously, by way of a capacitor, the current of which is derived from the voltage applied at the terminals thereof

When it detects the specified voltage threshold between the electrical terminals 11, 12 of the converter 10, the differential comparator 311a generates the first trigger signal, in the region of the amplifier, referred to as the first outlet S1.

According to a second embodiment, the first stage 311 of detecting the specified threshold makes use of the avalanche effect in a semiconductor (FIG. 5b). At a low voltage, the avalanche of a Zener diode may be used. At a high voltage, a transistor 311b can advantageously be used, for example, by making use of the avalanche between the gate and the drain of a MOS transistor. In this case, in order to prevent the source having a floating potential, the source can be connected to the gate (V_{GS}=0). As long as the voltage (potential difference between the electrical terminals 11, 12 of the converter 10) at the input of the first stage 311 is smaller than the MOS avalanche voltage, the transistor 311b is blocked and the outlet voltage Vs is zero. When the voltage at the input of the first stage 311 exceeds the avalanche threshold, the voltage at the outlet of the transistor Vs increases, and can be used to form the first trigger signal, at a first outlet S1.

In the first or the second embodiment cited, the second stage 312 of the control circuit 310 may comprise a logic device that is connected to the first outlet S1 and is thus capable of receiving the first trigger signal.

For each rising edge of the first signal, the logic device is designed for generating a second signal that forms a periodic pulse train, having a specified number of pulses, period and duty cycle (ratio between the pulse duration and the period of the pulse train).

The number of pulses may be between 20 and 150 and, as stated above, the width of the pulses may be between 10 and 1000 nanoseconds, and the period may be between 10 and 100 microseconds.

In this case, the second signal has a fixed pulse width, pulse period and number of pulses. Indeed, the logic device is predetermined so as to generate the pulse train, which fixes the characteristics of the second signal.

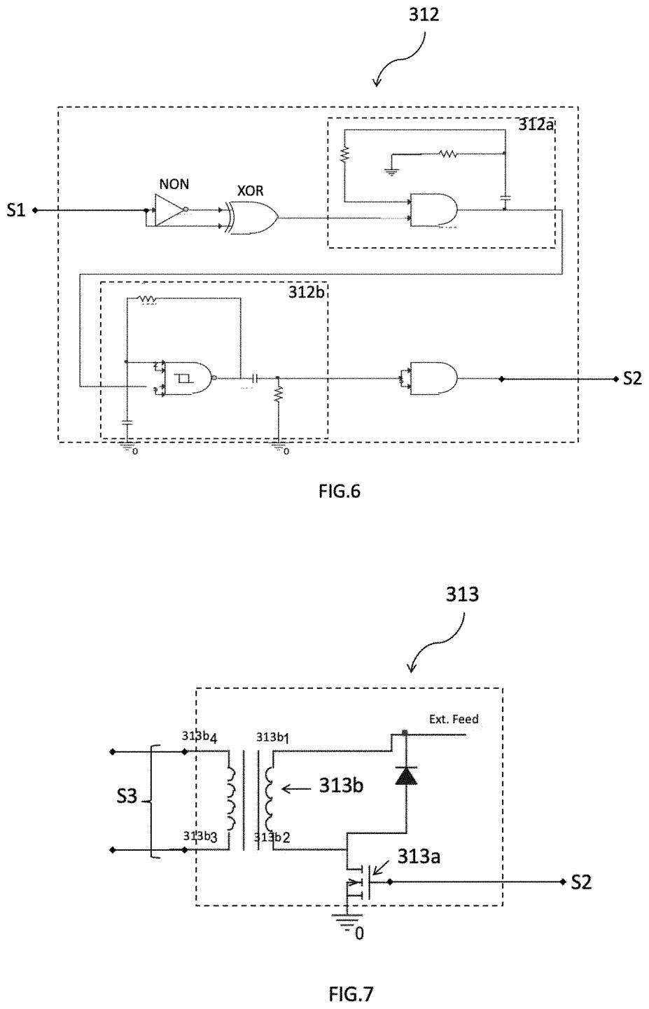

The logic device can be formed of logic ports as shown in FIG. 6. It comprises a first set of logic ports that allow for generation of a signal associated with each rising edge of the first signal.

The signal makes it possible to trigger a monostable assembly 312a, which defines a time during which a pulse train will be generated. The monostable assembly 312a triggers an astable assembly 312b, which will generate the pulse train. The astable assembly 312b typically has a period of a few tens of microseconds, and an opening duty cycle of close to 50%. Then, the width of each pulse is defined by means of an RC circuit.

The logic device forming the second stage 312 of the control circuit 310 thus makes it possible to generate, at the second output S2, a pulse train having the following features:
number of pulses: 15 to 150,
width of pulses: 10 to 1000 nanoseconds, for example, 600 nanoseconds,
and period: 10 to 100 microseconds, for example, 42 microseconds.

Forming the second stage 312 of the control circuit 310 from a logic device as described above has the advantage of an autonomous device, not requiring input of external energy in order to function.

Alternatively, the second stage 312 of the control circuit 310 may comprise a microcontroller that is designed for generating a second signal that forms a pulse train, at the second outlet S2. This alternative applies in the first or second embodiment set out above.

In this case, the second signal may have a variable and adjustable pulse width, pulse period and number of pulses, since the microcontroller can be programmed with variable parameters. This may make it possible to reduce the total duration of the pulse train. Indeed, at the start of the discharge (first closing-opening sequence of the switch 31), the potential difference Δv between the electrical terminals 11, 12 is high. The discharge during the first sequence, of a given duration, will provide much more energy than during a following sequence, of the identical duration, owing to the reduction in the potential difference Δv. It may thus be expedient to start the discharge by way of pulses having a short duration (short width) and to finish it with longer pulses (greater width). This makes it possible to harvest all the charges, using fewer pulses and in a shorter total time. At the same time, reducing the number of pulses makes it possible to reduce the switching losses and the energy consumption for the control. The yield can thus be improved.

By way of example, the microcontroller forming the second stage 312 of the control circuit 310 may make it possible to generate, at the second output S2, a pulse train having the following features:
number of pulses: <15,
width of pulses: 2 to 1000 nanoseconds, which may be variable between the first and the last pulse,
and period: 10 to 100 nanoseconds, which may be variable between the first and the last pulse.

According to a third embodiment of the present disclosure, the assembly formed by the first stage 311 and the second stage 312 may be formed by a microcontroller, which is able to detect the specified threshold of the potential difference at the electrical terminals 11, 12 of the converter 10, and, when the threshold is detected, to trigger generation of a second signal that forms a pulse train, at a second output S2.

It should be noted that using a microcontroller in the first stage 311 and second stage 312 of the control circuit 310 requires energy in order to function, and may thus vastly reduce a portion of the electrical energy harvested by the energy harvester 90. This energy, consumed by the microcontroller, is therefore no longer available for supplying an external electronic component. It is nonetheless possible to optimize the operation of the microcontroller by managing the standby phases thereof and/or by rationalizing the use of a microcontroller having other functions in a neighboring system.

In one or other of the embodiments described above, the third stage 313 of the control circuit 310 comprises an adaptation device that is connected to the second outlet S2 and is intended for transforming the second signal into a control signal that forms a pulse train and is capable of controlling the plurality of closing/opening sequences of the switch 31.

Advantageously, the adaptation device comprises a transistor 313a and a pulse transformer 313b. The gate of the transistor 313a is electrically connected to the second output S2 of the second stage 312 of the control circuit 310. Since the second signal forming the pulse train has a low voltage, it is necessary to transform it into a higher-voltage control signal for controlling the switch 31.

Advantageously, the switch 31 is formed by a transistor that is capable of maintaining a high tension (corresponding to the potential difference Δv between the electrical terminals 11, 12 of the converter) at the drain thereof that has a low parasitic capacity and can accept switching times that are less than a hundred of nanoseconds.

The pulse train of the second output S2 controls the gate of the transistor 313a. The input 313b1 of the primary winding of the pulse transformer 313b is connected to a feed voltage. The input 313b2 is connected to the drain of the transistor 313a. Toggling of the transistor 313a results in a change flux in the pulse transformer, and makes it possible to generate a control voltage on the second coil (output terminals 313b3 and 313b4). The output terminals 313b3, 313b4 of the pulse transformer 313b are connected, respectively, to the gate and the source of the transistor that forms the switch 31. The pulse transformer 313b thus makes it possible to isolate the low-voltage electronics (upstream of the pulse transformer 313b) from the high-voltage switch 31.

The energy harvester 90 according to the present disclosure has been described on the basis of the example of a magneto-electric converter 10. However, the present disclosure can be adapted to any type of converter 10 that includes a layer stack 9 comprising at least one first layer 1 made of a piezoelectric material, the amplitude of the change of the state of stress and of the stress dynamics of which is intended to be limited by means of controlled harvesting of charges by way of closing-opening sequences (partial successive discharges) of the switch 31 located between the converter 10 and the collection circuit 30.

Furthermore, the invention is not limited to the embodiments described, and it is possible to add variants thereto, without extending beyond the scope of the invention as defined by the claims.

1. An energy harvester, comprising:
a converter configured to convert a change in an energy to be harvested into a potential difference between two electrical terminals by accumulating charges on one or other of the terminals, the converter including a layer stack comprising at least one first layer comprising a piezoelectric material;
a collection circuit connected to the two electrical terminals and comprising a switch, the collection circuit configured to harvest the charges when the switch is in a closed state, the converter configured to emit acoustic vibrations in an audible frequency band when the collection circuit harvests the charges; and
a control circuit configured to control a plurality of closing/opening sequences of the switch when the potential difference reaches a defined threshold, so as to harvest the charges by way of a plurality of partial discharges of the converter, and to limit stress deviation to which the first layer is subjected during each discharge.

2. The energy harvester of claim 1, wherein, for each of the sequences, the closed state of the switch is controlled by a pulse generated by the control circuit.

3. The energy harvester of claim 2, wherein a pulse has a width of 100 to 1000 nanoseconds, and wherein two pulses of two consecutive sequences are spaced apart by 10 to 100 microseconds.

4. The energy harvester of claim 3, wherein the control circuit comprises a first stage for detecting a defined threshold of the potential difference, a second stage of generating the pulses, and a third stage of controlling the switch.

5. The energy harvester of claim 4, wherein the first stage comprises a differential comparator that is connected to the electrical terminals of the converter and is capable of generating a first trigger signal at a first outlet.

6. The energy harvester of claim 5, wherein the second stage comprises a logic device that is connected to the first outlet and is capable of generating a second signal that forms a pulse train at a second outlet.

7. The energy harvester of claim 6, wherein the second signal has a fixed pulse width, pulse period and number of pulses.

8. The energy harvester of claim 7, wherein the third stage comprises an adaptation device that is connected to the second outlet, in order to transform the second signal into a control signal that forms a pulse train capable of controlling the plurality of closing/opening sequences of the switch.

9. The energy harvester of claim 8, wherein the adaptation device comprises a transistor and a pulse transformer.

10. The energy harvester of claim 4, wherein the second stage or an assembly formed by the first and the second stage comprises a microcontroller that is designed for generating a second signal that forms a pulse train at a second outlet.

11. The energy harvester of claim 10, wherein the second signal has a variable pulse width, pulse period and number of pulses.

12. The energy harvester of claim 1, wherein the converter is a magneto-electric converter, which is capable of converting a change in magnetic energy into a potential difference between the two electrical terminals thereof, and the layer stack of which comprises a second layer made of a magnetorestrictive material.

13. An electricity generator comprising a magnetic field source and an energy harvester according to claim 1.

14. The energy harvester of claim 9, wherein the first trigger signal is generated when the potential difference at the electrical terminals of the converter is at a maximum.

15. The energy harvester of claim 1, wherein the specified threshold corresponds to a maximum potential difference between the two electrical terminals.

16. The energy harvester of claim 2, wherein the control circuit comprises a first stage for detecting a defined threshold of the potential difference, a second stage of generating the pulses, and a third stage of controlling the switch.

17. The energy harvester of claim 5, wherein the first trigger signal is generated when the potential difference at the electrical terminals of the converter is at a maximum.
